(19) United States
(12) Patent Application Publication
(10) Pub. No.: US 2026/0358854 A1
(43) Pub. Date: Nov. 12, 2026

(54) DISPLAY DEVICE CASING

(71) Applicant: LG ELECTRONICS INC., Seoul (KR)

(72) Inventors: Jaehyeok BAE, Seoul (KR); Seayoung CHO, Seoul (KR); Wuram CHOI, Seoul (KR); Jingyu KIM, Seoul (KR); Sunghun LEE, Seoul (KR)

(73) Assignee: LG ELECTRONICS INC., Seoul (KR)

(21) Appl. No.: 19/119,251

(22) PCT Filed: Nov. 29, 2023
(86) PCT No.: PCT/KR2023/019429

§ 371 Date: Apr. 8, 2025

(30) Foreign Application Priority Data
Nov. 14, 2023 (KR) 10-2023-0157235

(51) Int. Cl. G06F 1/16; A45C 11/00; A45C 13/10

(52) U.S. Cl. CPC G06F 1/1629; A45C 11/003; A45C 13/1069; A45C 2200/15

(57) ABSTRACT

Disclosed is a display device casing including a rear cover covering a rear surface of a display module, a side cover surrounding peripheries of side surfaces of the display module and having a fastening groove defined at one side thereof, a folio cover having a portion-to-be-inserted formed at one end thereof to be inserted into the fastening groove, and a fixing bracket coupled to one side of the side cover and including a first magnet having one surface in contact with one surface of the inserted portion-to-be-inserted, wherein the portion-to-be-inserted includes a second magnet generating a magnetic force with the first magnet. The display device increases an adhesive force of the folio cover via a structure in which the portion-to-be-inserted formed at one end of the folio cover is inserted into the fastening groove defined in the side cover.

### TECHNICAL FIELD

The present disclosure relates to a display device casing that may stably mount a large-screen display device while protecting an outer appearance of the device.

### BACKGROUND

As an information society develops, a demand for a display device is also increasing in various forms. In response thereto, recent display devices include a liquid crystal display (LCD), a field emission display (FED), a plasma display panel (PDP), an electroluminescent device, and the like.

In addition, recently, the display has been enlarged, and functions of the display device have been gradually diversified.

For example, in case of a tablet, there are functions of data and voice communication, photographing and video shooting via a camera, voice recording, reproduction of a music file via a speaker system, and outputting an image or a video on a display. In addition, the tablet may have an electronic game play function added or perform a multimedia player function.

As the functions of the display device are diversified, a time spent using the display device increases, so that it is difficult for a user to hold the display device by hand for a long time. Additionally, to watch the image output on the display device while doing other tasks simultaneously, there is a need to mount the display device upright without holding the same.

To this end, a casing for mounting the display device is being released. Such existing casing adopts a detachment scheme using a magnet. For example, it is a scheme of using a magnetic force between a magnet located at one side of a side casing and a magnet located at one side of a foldable folio cover. Accordingly, the user may easily mount the display device while increasing convenience of carrying.

However, because the display is enlarged as described above, the simple detachment scheme using the magnet like the existing casing has a limitation in an adhesive force. This is because a size of the casing should also be increased accordingly as the display device is enlarged, and a weight of the casing accordingly increases.

In addition, to properly support a weight of the display device, it is necessary to secure the adhesive force of the casing. Otherwise, the casing may not be able to support the weight of the display device and may be deviated to cause damage to the display device.

Therefore, a means for securing the adhesive force of the casing is required to protect an outer appearance of the large-screen display device and to stably mount the display device at the same time.

### SUMMARY

### Technical Problem

The present disclosure is to provide a display device casing and, more specifically, is to a display device casing that may increase an adhesive force of a folio cover via a structure in which a portion-to-be-inserted formed at one end of the folio cover is inserted into a fastening groove defined in a side cover.

In addition, the present disclosure is to provide a display device casing that may increase an adhesive force of a folio cover by minimizing a gap between magnets for fastening the folio cover and increasing an area size for generating a magnetic force.

In addition, the present disclosure to provide a display device casing that may block foreign substances that may be introduced via a fastening groove after a folio cover is fastened via a fixing rib formed to protrude from a front surface of a rear cover.

The problems to be solved by the present disclosure are not limited to the above-mentioned technical problems, and other technical problems not mentioned will be clearly understood by those skilled in the art to which the present disclosure pertains from the following description.

### Technical Solutions

Provided is a display device casing including a rear cover covering a rear surface of a display module, a side cover surrounding peripheries of side surfaces of the display module and having a fastening groove defined at one side thereof, a folio cover having a portion-to-be-inserted formed at one end thereof to be inserted into the fastening groove, and a fixing bracket coupled to one side of the side cover and including a first magnet having one surface in contact with one surface of the inserted portion-to-be-inserted, wherein the portion-to-be-inserted includes a second magnet generating a magnetic force with the first magnet.

The first magnet may have the one surface formed by coupling a plurality of magnets to each other with an N-pole and an S-pole alternately arranged.

The second magnet may have one surface formed by coupling a plurality of magnets to each other with an S-pole and an N-pole alternately arranged to generate the magnetic force with the N-pole and the S-pole of the first magnet.

The first magnet may include a marking plate coupled to one side surface thereof.

The first magnet may have the one surface disposed to be perpendicular to an inner surface of the side cover.

The rear cover may include a fixing rib protruding from a front surface thereof and in contact with an opposite surface of the inserted portion-to-be-inserted.

The fixing rib may be formed to be inclined to protrude from one side toward an inner side of the rear cover.

The fixing rib may include a plurality of fixing ribs spaced apart from each other and formed in parallel with each other.

The folio cover may include a bent portion so as to be foldable, and the folio cover may have an opposite end in contact with one side of a rear surface of the rear cover in a state of being folded in a first state.

The rear cover may include an engagement groove defined in the rear surface thereof, wherein the opposite end of the folio cover is inserted into the engagement groove.

The folio cover may include an engagement portion formed to extend in a foldable manner from the opposite end thereof, and the engagement portion may be folded and inserted into the engagement groove.

The engagement groove may include a plurality of engagement grooves spaced apart from each other and formed in parallel with each other.

The folio cover may cover a front surface of the display module in a state of being folded in a second state.

The folio cover may include an engagement portion formed to extend in a foldable manner from the opposite end thereof, and the engagement portion may be folded and come into contact with an opposite side of the side cover.

### Advantageous Effects

The display device casing according to the present disclosure may increase the adhesive force of the folio cover via the structure in which the portion-to-be-inserted formed at the one end of the folio cover is inserted into the fastening groove defined in the side cover.

In addition, the display device casing according to the present disclosure may increase the adhesive force of the folio cover by minimizing the gap between the magnets for fastening the folio cover and increasing the area size for generating the magnetic force.

In addition, the display device casing according to the present disclosure may block the foreign substances that may be introduced via the fastening groove after the folio cover is fastened via the fixing rib formed to protrude from the front surface of the rear cover.

The effects obtainable in the present disclosure are not limited to the effects mentioned above, and other effects not mentioned may be clearly understood by those skilled in the art to which the present disclosure pertains from the following description.

### BRIEF DESCRIPTION OF THE DRAWINGS

FIG. 1 is a block diagram illustrating each configuration of a display device according to embodiments.

FIG. 2 is a perspective view of a display device casing according to an embodiment of the present disclosure.

FIG. 3 is a view illustrating a state in which a folio cover is folded in a first state in a display device casing according to an embodiment of the present disclosure.

FIG. 4 is a view illustrating a state in which a folio cover is unfolded in a display device casing according to an embodiment of the present disclosure.

FIG. 5 is a bottom view of an area A in FIG. 4.

FIG. 6 is a view illustrating a folio cover in a display device casing according to an embodiment of the present disclosure.

FIG. 7 is a view illustrating a fixing bracket coupled to a side cover in an area A in FIG. 5.

FIG. 8 is a view illustrating a first magnet positioned at a fixing bracket in a display device casing according to an embodiment of the present disclosure.

FIG. 9 is a perspective view of an area B in FIG. 4.

FIG. 10 is a view illustrating a fixing rib formed on a rear cover in a display device casing according to an embodiment of the present disclosure.

FIG. 11 is a view illustrating a state in which a folio cover is folded in a second state in a display device casing according to an embodiment of the present disclosure.

FIG. 12 is a view illustrating another embodiment of a first magnet in a display device casing according to the present disclosure.

FIG. 13 is a view illustrating another embodiment of a second magnet positioned at a portion-to-be-inserted of a folio cover in a display device casing according to the present disclosure.

### BEST MODE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

In one example, a display device described herein is, for example, an intelligent display device in which a computer support function is added to a broadcast reception function. As an Internet function is added while being faithful to the broadcast reception function, the display device may be equipped with a more convenient interface for use, such as a handwriting-type input device, a touch screen, or a spatial remote control. In addition, the display device is also able to perform functions such as e-mailing, web browsing, banking, or gaming by connecting to the Internet and a computer with support of a wired or wireless Internet function. Standardized general purpose OS may be used for such various functions.

Accordingly, the display device described herein may freely add or delete various applications on a general-purpose OS kernel, for example, and thus may perform various user-friendly functions. More specifically, the display device may be, for example, a network TV, a HBBTV, a smart TV, or the like, and may be applied to a smartphone in some cases.

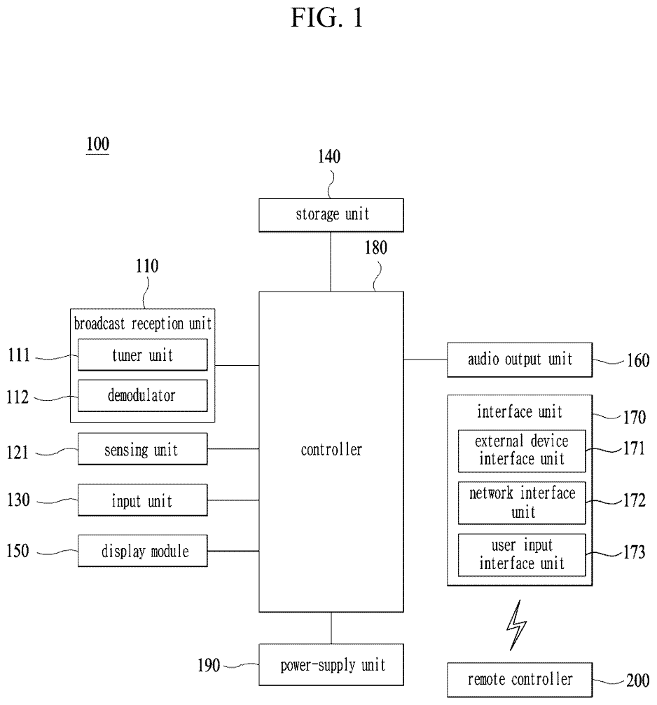

FIG. 1 is a block diagram illustrating each configuration of a display device 100 according to embodiments. Referring to FIG. 1, a display device 100 may include a broadcast reception unit 110, a sensing unit 120, an external device interface unit 171, a network interface unit 172, a storage unit 140, a user input interface unit 173, an input unit 130, a controller 180, a display module 150, an audio output unit 160, and/or a power supply unit 190.

The broadcast reception unit 110 may include a tuner unit 111 and a demodulator 112.

Meanwhile, unlike the drawing, the display device 100 may include only the external device interface unit 171 and the network interface unit 172 among the broadcast reception unit 110, the external device interface unit 171, and the network interface unit 172. That is, the display device 100 may not include the broadcast reception unit 110.

The tuner unit 111 may select a broadcast signal corresponding to a channel selected by a user or all pre-stored channels from broadcast signals received through an antenna (not shown) or a cable (not shown). The tuner unit 111 may convert the selected broadcast signal into an intermediate frequency signal or a baseband video or audio signal.

For example, if the selected broadcast signal is a digital broadcast signal, the tuner unit 111 may convert the selected broadcast signal into a digital IF signal (DIF). If the selected broadcast signal is an analog broadcast signal, the tuner unit 111 may convert it into an analog baseband video or audio signal (CVBS/SIF). That is, the tuner unit 111 may process a digital broadcast signal or an analog broadcast signal. The analog baseband video or audio signal (CVBS/SIF) outputted from the tuner unit 111 may be directly inputted to the controller 180.

On the other hand, the tuner unit 111 may sequentially select broadcast signals of all stored broadcast channels through a channel memory function from the received broadcast signals and convert them into intermediate frequency signals or baseband video or audio signals.

Meanwhile, the tuner unit 111 may include a plurality of tuners to receive broadcast signals of a plurality of channels. Alternatively, a single tuner that simultaneously receives broadcast signals of a plurality of channels is also available.

The demodulator 112 may perform a demodulation operation by receiving the digital IF signal (DIF) converted by the tuner unit 111. The demodulator 112 may output a stream signal (TS) after performing demodulation and channel decoding. In this case, the stream signal may be a signal obtained by multiplexing a video signal, an audio signal, and/or a data signal.

The stream signal outputted from the demodulator 112 may be inputted to the controller 180. The controller 180 may output a video and an audio through the display module 150 and the audio output unit 160 after performing demultiplexing, audio/video signal processing, and the like.

The sensing unit 120 refers to a device that detects or senses a change inside or outside the display device 100. For example, it may include at least one of a proximity sensor, an illumination sensor, a touch sensor, an infrared (IR) sensor, an ultrasonic sensor, an optical sensor (e.g., a camera), a voice sensor (e.g., a microphone), a battery gauge, an environmental sensor (e.g., a humidity meter, a thermometer, etc.).

The controller 180 may check a state of the display device 100 based on the information collected by the sensing unit 120 and inform a user of it when a problem occurs or adjust it by itself to maintain a best state.

In addition, the controller 180 may provide an optimal viewing environment by controlling a content, image quality, size, etc. of a video provided to the display module 180 differently depending on a viewer, an ambient illuminance, and the like detected by the sensing unit. As smart TVs advance, the number of functions installed on display devices increases, and the sensing unit 20 is also increasing together with the functions.

The input unit 130 may be provided on one side of a body of the display device 100. For example, the input unit 130 may include a touch pad, a physical button, and the like. The input unit 130 may receive various user commands related to operations of the display device 100 and transmit control signals corresponding to the inputted commands to the controller 180.

Recently, as a bezel of the display device 100 decreases in size, many display devices 100 tend to minimize the input unit 130 in the form of physical buttons exposed to the outside. Instead, minimum physical buttons are located on a rear or side surface and a user input may be received through a touch pad, the user input interface unit 173, or a remote controller 200 to be described later.

The storage unit 140 may store a program for each signal processing and control in the controller 180, or may store a signal-processed video, audio, or data signal. For example, the storage unit 140 may store application programs designed to perform various tasks which may be processed by the controller 180, and selectively provide some of the stored application programs upon request of the controller 180.

The program and the like stored in the storage unit 140 may not be particularly limited as long as they can be executed by the controller 180. The storage unit 140 may perform a function of temporarily storing a video, audio, or data signal received from an external device through the external device interface unit 171. The storage unit 140 may store information on a prescribed broadcast channel through a channel memory function such as a channel map.

Although FIG. 1 shows an embodiment in which the storage unit 140 is provided separately from the controller 180, the scope of the present disclosure is not limited thereto, and the storage unit 140 may be included in the controller 180.

The storage unit 140 may include at least one of a volatile memory (e.g., DRAM, SRAM, SDRAM, etc.) or a nonvolatile memory (e.g., a flash memory, a Hard Disk Drive (HDD), a Solid-State Drive (SSD), etc.).

The display module 150 may generate a driving signal by converting a video signal, a data signal, an OSD signal, and a control signal processed by the controller, or a video signal, a data signal, a control signal, and the like received from the interface unit 171. The display module 150 may include a display panel including a plurality of pixels.

The display module 150 may be a flexible display or the like, or may be a 3-dimensional display (3D display). The 3-dimensional display module 150 may be categorized into a non-glasses type and a glasses type.

The display device 100 may include the display module 150 that occupies a significant portion of an area size on a front surface thereof, and a casing that covers a rear surface, side surfaces, and the like of the display module 150 and packages the display module 150.

The display module 150 may include a copuling magnet, a first power supply, and a first signal module.

In the display module 150, a side where the image is displayed may be referred to as a front side or a front surface. When the display module 150 displays the image, a side where the image is not able to be observed may be referred to as a rear side or a rear surface. In one example, the display module 150 may be equipped as a touch screen and be used as an input device in addition to the output device.

The audio output unit 160 receives an input of a signal audio-processed by the controller 180 and outputs it as an audio.

The interface unit 170 serves as a passage with various types of external devices connected to the display device 100. The interface unit 170 may include a wireless system using an antenna as well as a wired system for transmitting and receiving data through a cable.

The interface unit 170 may include at least one of a wired/wireless headset port, an external charger port, a wired/wireless data port, a memory card port, a port for connecting a device having an identification module, an audio Input/Output (I/O) port, a video Input/Output (I/O) port, an earphone port, etc.

As an example of the wireless system, the above-described broadcast reception unit 110 may be included, and not only a broadcast signal but also a mobile communication signal, a short-range communication signal, a wireless Internet signal, and the like may be included.

The external device interface unit 171 may transmit or receive data to or from a connected external device. To this end, the external device interface unit 171 may include an A/V input/output unit (not shown).

The external device interface unit 171 may be connected to an external device such as a Digital Versatile Disk (DVD), a Blu-ray, a game device, a camera, a camcorder, a computer (a notebook), a set-top box, and the like by wire or wirelessly, and may perform input/output operations with the external device.

In addition, the external device interface unit 171 may establish a communication network with various remote controllers 200 to receive control signals related to the operation of the display device 100 from the remote controller 200 or transmit data related to the operation of the display device 100 to the remote controller 200.

The external device interface unit 171 may include a wireless communication unit (not shown) for short-range wireless communication with another electronic device. Through the wireless communication unit (not show), the external device interface unit 171 may exchange data with an adjacent mobile terminal. Particularly, in a mirroring mode, the external device interface unit 171 may receive device information, executed application information, application image, and the like from the mobile terminal.

The network interface unit 172 may provide an interface for connecting the display device 100 to a wired/wireless network including an Internet network. For example, the network interface unit 172 may receive content or data provided by Internet, a content provider, or a network operator over a network. Meanwhile, the network interface unit 172 may include a communication module (not shown) for connection with a wired/wireless network.

The external device interface unit 171 and/or the network interface unit 172 may include a communication module for short-range communication such as Wireless-Fidelity (Wi-Fi), Bluetooth, Bluetooth Low Energy (BLE), Zigbee, and Near Field Communication (NFC), a communication module for cellular communication such as Long-Term Evolution (LTE), LTE-Advance (LTE-A), Code Division Multiple Access (CDMA), Wideband CDMA (WCDMA), Universal Mobile Telecommunications System (UMTS), Wireless Broadband (WiBro), and the like.

The user input interface unit 173 may transmit a signal inputted by a user to the controller 180, or transmit a signal from the controller 180 to the user. For example, it may transmit/receive a user input signal such as power on/off, channel selection, screen setting, and the like to/from the remote controller 200, forward a user input signal inputted from a local key (not shared) such as a power key, a channel key, a volume key, a setting value, and the like to the controller 180, forward a user input signal inputted from a sensor unit (not shared) that senses a user's gesture to the controller 180, or transmit a signal from the controller 180 to the sensor unit.

The controller 180 may include at least one processor, and may control the overall operation of the display device 100 by using a processor included therein. Here, the processor may include a general processor such as a Central Processing Unit (CPU). Of course, the processor may include a dedicated device such as an ASIC or another hardware-based processor.

The controller 180 may generate and output a signal for a video or audio output by demultiplex a stream inputted through the tuner unit 111, the demodulator 112, the external device interface unit 171, or the network interface unit 172 or processing the demultiplexed signals.

The video signal video-processed by the controller 180 may be inputted to the display module 150 and displayed as a video corresponding to the video signal. In addition, the video signal video-processed by the controller 180 may be inputted to an external output device through the external device interface unit 171.

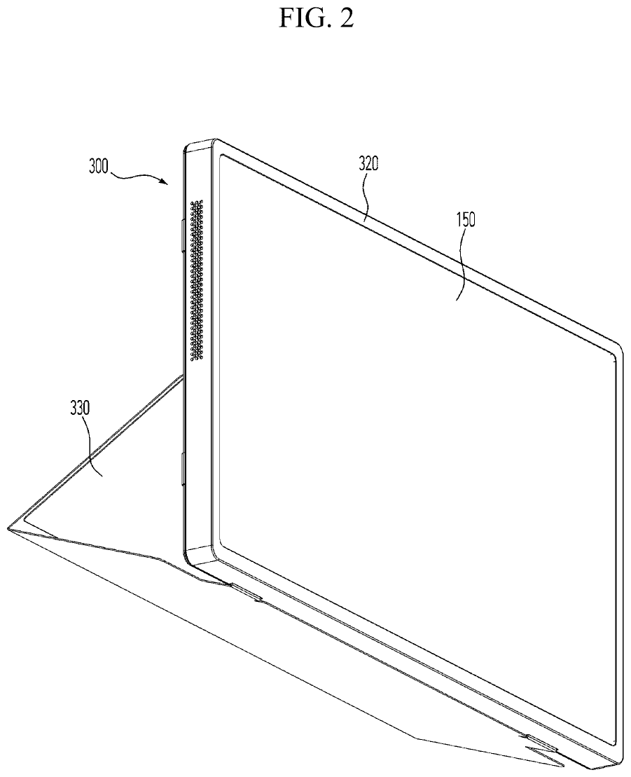

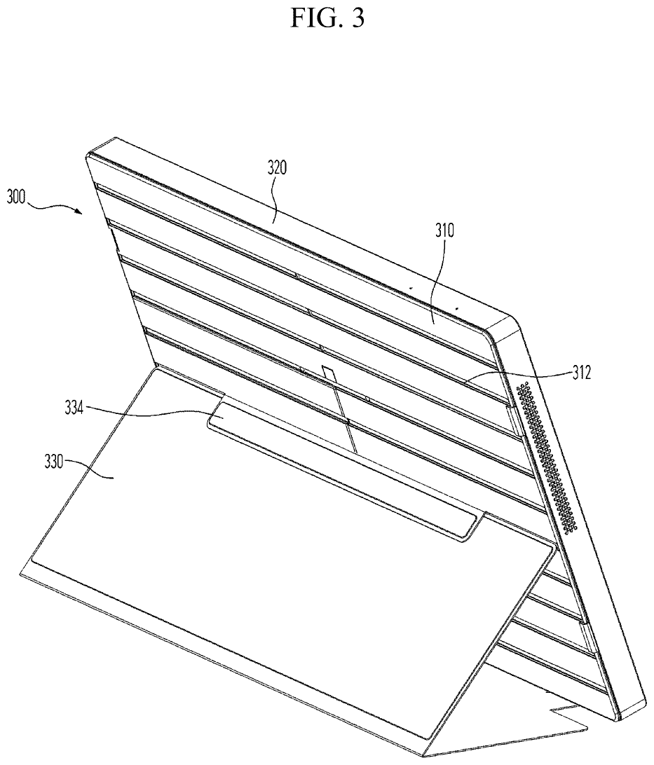

The audio signal processed by the controller 180 may be outputted to the audio output unit 160. Also, the audio signal processed by the controller 180 may be inputted to an external output device through the external device interface unit 171. Although not shown in FIG. 2, the controller 180 may include a demultiplexing unit, a video processing unit, and the like. This will be described later with reference to FIG. 3.

Besides, the controller 180 may control the overall operation of the display device 100. For example, the controller 180 may control the tuner unit 111 to select (e.g., tune) a broadcast corresponding to a channel selected by a user or a pre-stored channel.

In addition, the controller 180 may control the display device 100 by a user command inputted through the user input interface unit 173 or an internal program. Meanwhile, the controller 180 may control the display module 150 to display an image. In this case, the image displayed on the display module 150 may be a still image or a moving image, and may be a 2D image or a 3D image.

Meanwhile, the controller 180 may display a predetermined 2D object in the image displayed on the display module 150. For example, the object may include at least one of a connected web screen (e.g., newspaper, magazine, etc.), an Electronic Program Guide (EPG), one of various menus, a widget, an icon, a still image, a moving image, and texts.

Meanwhile, the controller 180 may modulate and/or demodulate a signal using an Amplitude Shift Keying (ASK). Here, the amplitude shift modulation (ASK) may mean a method of modulating a signal by varying the amplitude of a carrier wave according to a data value or restoring an analog signal to a digital data value according to the amplitude of the carrier wave.

For example, the controller 180 may modulate a video signal using Amplitude Shift Keying (ASK) and transmit it through a wireless communication module.

For example, the controller 180 may demodulate and process a video signal received through a wireless communication module using Amplitude Shift Keying (ASK).

Through this, the display device 100 may easily transmit and receive signals to and from other adjacent image display devices without using a unique identifier such as a Media Access Control (MAC) address or a complex communication protocol such as TCP/IP.

Meanwhile, the display device 100 may further include a photographing unit (not shown). The photographing unit may photograph a user. The photographing unit may be implemented with a single camera, but is not limited thereto, and may also be implemented with a plurality of cameras. Meanwhile, the photographing unit may be embedded in an upper portion of the display module 150 of the display device 100 or separately disposed. Image information photographed by the photographing unit may be inputted to the controller 180.

The controller 180 may recognize a user's location based on an image photographed by the photographing unit. For example, the controller 180 may recognize a distance (e.g., a z-axis coordinate) between the user and the display device 100. In addition, the controller 180 may recognize an x-axis coordinate and a y-axis coordinate in the display module 150 corresponding to the user's location.

The controller 180 may detect a user's gesture based on an image photographed by the photographing unit, each signal sensed from the sensor unit, or a combination thereof.

The power supply unit 190 may supply corresponding power to the display device 100 overall. In particular, power may be supplied to the controller 180, which may be implemented in the form of a System-On-Chip (SOC), the display module 150 for displaying an image, the audio output unit 160 for audio output, etc.

Specifically, the power supply unit 190 may include a converter (not shown) that converts AC power into DC power, and a Dc/Dc converter (not shown) that converts a level of the DC power.

Meanwhile, the power supply unit 190 serves to receive power from the outside and distribute the power to each component. The power supply unit 190 may use a method of supplying AC power by directly connecting with external power, and a power supply unit 190 usable in a manner of charging a battery included therein may be included.

In the former case, a wired cable is connected and used, and movement is difficult or a range of movement is limited. In the latter case, although it is free to move, the weight and volume increase as much as the battery, and for charging, it should be connected to a power cable directly for a predetermined time or combined with a charging holder (not shown) that supplies power.

The charging holder may be connected to the display device through a terminal exposed to the outside, or a built-in battery may be charged when the charging holder is approached using a wireless method.

The remote controller 200 may transmit a user input to the user input interface 173. To this end, the remote controller 200 may use Bluetooth, Radio Frequency (RF) communication, Infrared Radiation (IR) communication, Ultra-WideBand (UWB), ZigBee, etc. In addition, the remote controller 200 may receive a video, an audio, a data signal, or the like outputted from the user input interface unit 173 and the received image, audio, data signal or the like may be displayed or outputted by the remote controller 200.

Meanwhile, the above-described display device 100 may include a stationary or mobile digital broadcast receiver capable of receiving digital broadcasting.

Meanwhile, the block diagram of the display device 100 shown in FIG. 1 is only a block diagram for an embodiment of the present disclosure, and each component of the block diagram may be integrated, added, or omitted depending on the specifications of the display device 100 that is actually implemented.

That is, two or more components may be combined or integrated into one component, or one component may be subdivided into two or more components as necessary. In addition, a function performed in each block is for describing an embodiment of the present disclosure, and a specific operation or device does not limit the scope of rights of the present disclosure.

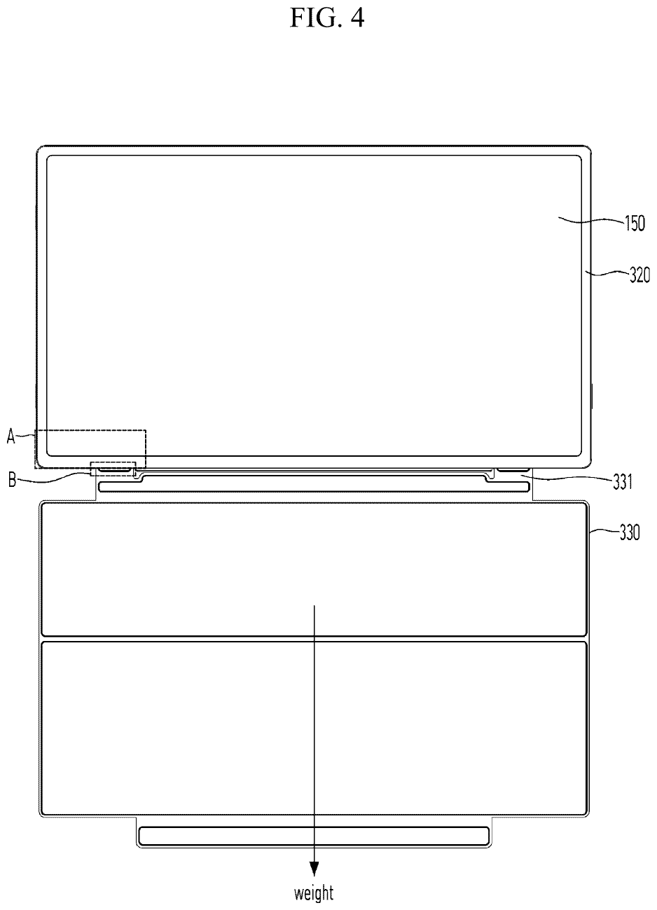

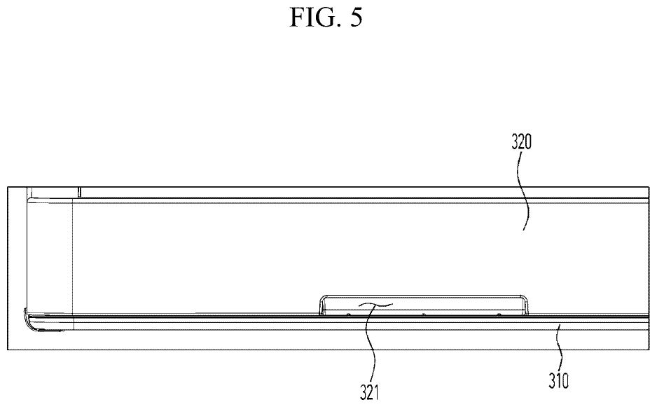

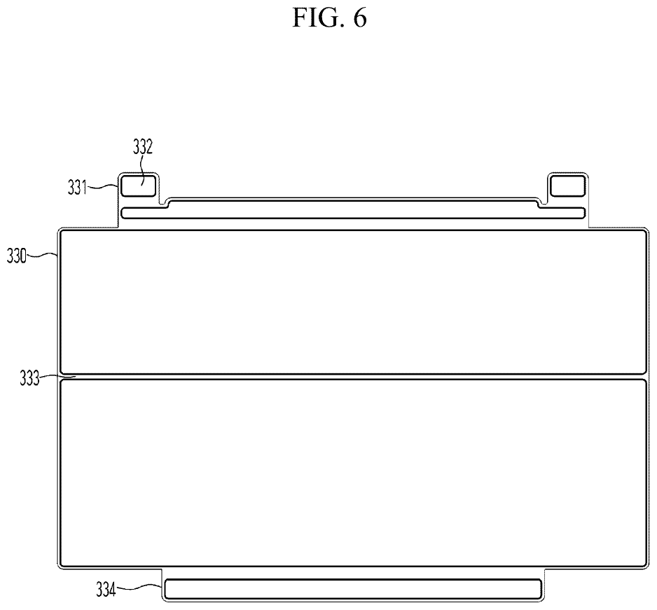

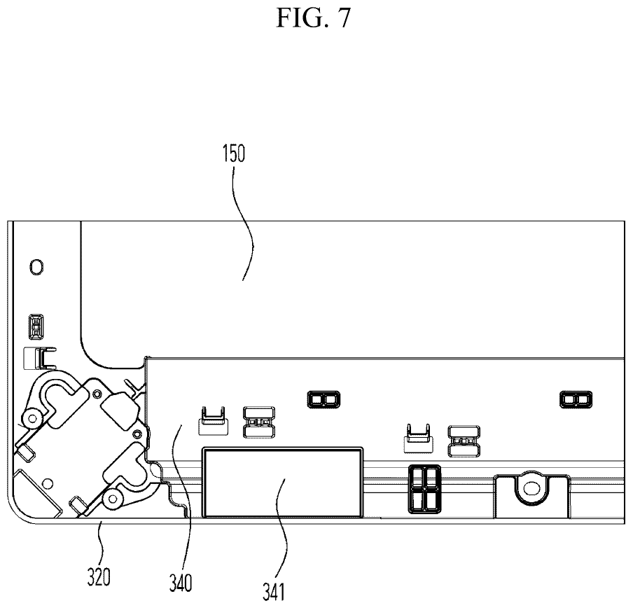

FIG. 2 is a perspective view of a display device casing 300 according to an embodiment of the present disclosure. FIG. 3 is a view illustrating a state in which a folio cover 330 is folded in a first state in the display device casing 300 according to an embodiment of the present disclosure. FIG. 4 is a view illustrating a state in which the folio cover 330 is unfolded in the display device casing 300 according to an embodiment of the present disclosure. FIG. 5 is a bottom view of an area A in FIG. 4. FIG. 6 is a view illustrating the folio cover 330 in the display device casing 300 according to an embodiment of the present disclosure. Further, FIG. 7 is a view illustrating a fixing bracket 340 coupled to a side cover 320 in the area A in FIG. 5.

Referring to FIGS. 2 to 7 together, the display device casing 300 according to an embodiment of the present disclosure may include a rear cover 310, the side cover 320, the folio cover 330, and the fixing bracket 340.

In this regard, the rear cover 310 may cover a rear surface of the display module 150 described above with reference to FIG. 1. In addition, the side cover 320 may surround peripheries of side surfaces of the display module 150 and have a fastening groove 321 defined at one side thereof. In addition, a portion-to-be-inserted 331, which is inserted into the fastening groove 321 of the side cover 320, may be formed at one end of the folio cover 330. The fixing bracket 340 may be coupled to one side of the side cover 320. In addition, a first magnet 341 having one surface in contact with one surface of the portion-to-be-inserted 331 of the folio cover 330 inserted into the fastening groove 321 may be positioned in the fixing bracket 340.

In particular, in the display device casing 300 according to an embodiment of the present disclosure, a second magnet 332 that generates a magnetic force with the first magnet 341 located at the fixing bracket 340 may be located at the portion-to-be-inserted 331 formed at the folio cover 330.

As described above, the display device casing 300 according to an embodiment of the present disclosure is intended to stably mount the display while protecting an outer appearance of the large-screen display device as the display is enlarged. This is because a simple detachment scheme using a magnet as in an existing casing has a limitation in an adhesive force.

Referring to FIG. 4 together, as the display is enlarged, a size of the folio cover 330 should also increase to a size corresponding thereto. Accordingly, a weight of the folio cover 330 inevitably increases. As a result, to stably couple the folio cover 330 to the side cover 320, it is necessary to sufficiently secure the adhesive force.

Therefore, referring to FIGS. 5 and 6 together, the display device casing 300 according to an embodiment of the present disclosure may define the fastening groove 321 at one side of the side cover 320. In addition, the portion-to-be-inserted 331 formed at one end of the folio cover 330 may be inserted into the fastening groove 321.

In this regard, the first magnet 341 positioned at the fixing bracket 340 and the second magnet 332 positioned at the portion-to-be-inserted 331 may generate the magnetic force. In this case, the first magnet 341 and the second magnet 332 are spaced apart from each other by only a thickness of the folio cover 330. Accordingly, a gap between the first magnet 341 and the second magnet 332 may be minimized.

As a result, compared to the simple detachment scheme using the magnet of the existing casing, because the display device casing 300 according to an embodiment of the present disclosure may minimize the gap between the first magnet 341 and the second magnet 332 via the insertion structure of the folio cover 330, it is advantageous to secure the magnetic force between the first magnet 341 and the second magnet 332. In addition, accordingly, the adhesive force of the folio cover 330 may be sufficiently secured.

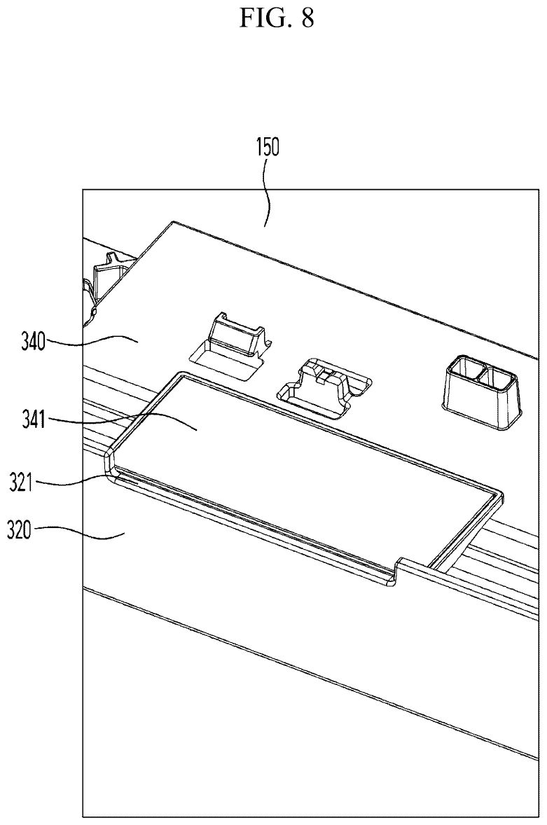

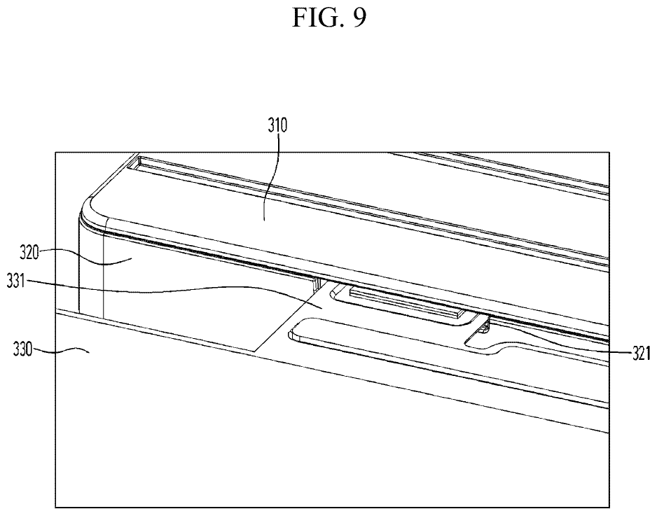

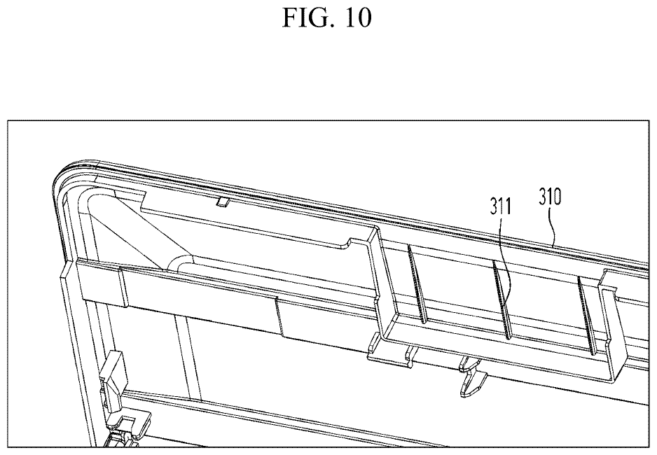

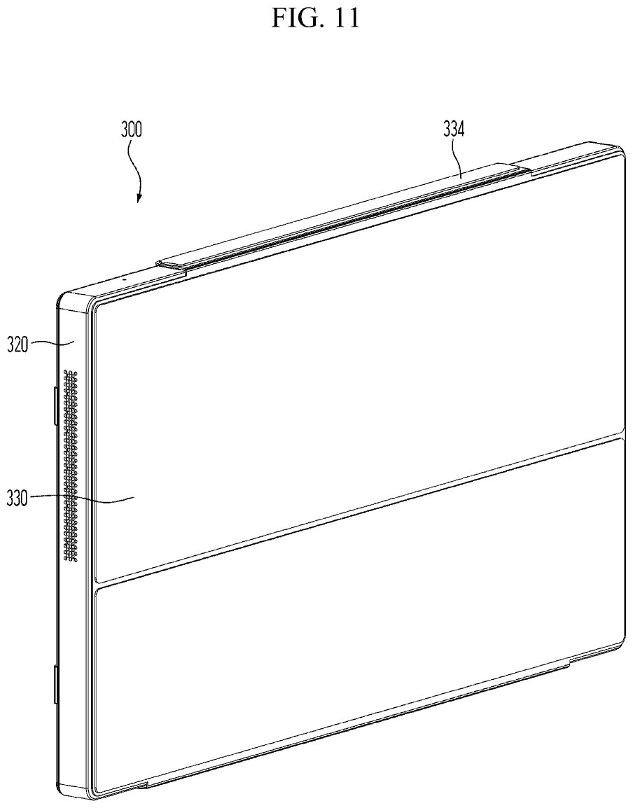

FIG. 8 is a view illustrating the first magnet 341 positioned at the fixing bracket 340 in the display device casing 300 according to an embodiment of the present disclosure. FIG. 9 is a perspective view of an area B in FIG. 4. FIG. 10 is a view illustrating a fixing rib 311 formed on the rear cover 310 in the display device casing 300 according to an embodiment of the present disclosure. Further, FIG. 11 is a view illustrating a state in which the folio cover 330 is folded in a second state in the display device casing 300 according to an embodiment of the present disclosure.

In the display device casing 300 according to an embodiment of the present disclosure, as described above, the first magnet 341 may be positioned at the fixing bracket 340 coupled to one side of the side cover 320. In this regard, as illustrated in FIG. 8, one surface of the first magnet 341 may be disposed to be perpendicular to an inner surface of the side cover 320.

This is to increase an area size in which the first magnet 341 and the second magnet 332 may generate the magnetic force when the portion-to-be-inserted 331 of the folio cover 330 is inserted into the fastening groove 321 defined in the side cover 320.

That is, in the display device casing 300 according to an embodiment of the present disclosure, the gap between the first magnet 341 and the second magnet 332 may be minimized, and the area size for generating the magnetic force may be increased, thereby increasing the adhesive force of the folio cover 330. Accordingly, the number of magnets for attaching the folio cover 330 to the side cover 320 may be minimized, thereby reducing costs.

In addition, in the display device casing 300 according to an embodiment of the present disclosure, the rear cover 310 may include the fixing rib 311 formed to protrude from a front surface thereof and in contact with the other surface of the portion-to-be-inserted 331 of the folio cover 330 inserted into the fastening groove 321.

In this regard, the display device casing 300 according to an embodiment of the present disclosure may stably fix the portion-to-be-inserted 331 of the folio cover 330 inserted into the fastening groove 321 via the fixing rib 311. In addition, via the fixing rib 311, foreign substances that may be introduced via the fastening groove 321 after the folio cover 330 is inserted may be blocked.

In addition, referring to FIG. 10 together, in the display device casing 300 according to an embodiment of the present disclosure, the fixing rib 311 may be formed to be inclined to protrude from one side toward an inner side of the rear cover 310. Further, a plurality of fixing ribs 311 may be formed to be spaced apart from each other and in parallel with each other.

This is to allow the user to easily separate the folio cover 330 after the folio cover 330 is fastened. That is, a space may be defined between one side of the rear cover 310 and the portion-to-be-inserted 331 of the folio cover 330 via the fixing rib 311 formed in the inclined manner, and the user may easily separate the portion-to-be-inserted 331 of the folio cover 330 that is generating the magnetic force with the first magnet 341 by pressing the portion-to-be-inserted 331.

Accordingly, the display device casing 300 according to an embodiment of the present disclosure may sufficiently secure the magnetic force between the first magnet 341 and the second magnet 332 via the structure of inserting the folio cover 330 into the side cover 320, thereby increasing the adhesive force of the folio cover 330. At the same time, the user may easily separate the folio cover 330 by pressing the portion-to-be-inserted 331 via the fixing rib 311 formed in the inclined manner on the rear cover 310, thereby further improving convenience of use.

Referring back to FIGS. 3 and 6, in the display device casing 300 according to an embodiment of the present disclosure, the folio cover 330 may include a bent portion 333 to be foldable. In addition, as illustrated in FIG. 3, in the state in which the folio cover 330 is folded in the first state, the other end of the folio cover 330 may be in contact with one side of the rear surface of the rear cover 310, thereby supporting the display device.

In addition, as illustrated in FIG. 3, in the display device casing 300 according to an embodiment of the present disclosure, the rear cover 310 may include an engagement groove 312 defined in the rear surface thereof and into which the other end of the folio cover 330 is inserted. Accordingly, the large-screen display device may be more stably supported.

In addition, in the display device casing 300 according to an embodiment of the present disclosure, the folio cover 330 may include an engagement portion 334 formed to extend in a foldable manner from the other end thereof. Accordingly, as shown in FIG. 3, as the engagement portion 334 is folded, a thickness of the other end of the folio cover 330 may be increased, and as the engagement portion 334 is fitted into the engagement groove 312, the large-screen display device may be more stably supported.

In addition, as illustrated in FIG. 3, in the display device casing 300 according to an embodiment of the present disclosure, the engagement groove 312 defined in the rear surface of the rear cover 310 may include a plurality of engagement grooves spaced apart from each other and defined in parallel with each other. Accordingly, the user may easily adjust an angle at which the display device is erected based on convenience.

In addition, referring to FIGS. 3 and 11 together, in the display device casing 300 according to an embodiment of the present disclosure, the folio cover 330 may cover a front surface of the display module 150 in the state of being folded in the second state. That is, the folio cover 330 may support the display device in the state of being folded in the first state, and may cover the front surface of the display module 150 and protect the outer appearance of the large-screen display device in the state of being folded in the second state.

Additionally, as illustrated in FIG. 11, in the display device casing 300 according to an embodiment of the present disclosure, the folio cover 330 may include the engagement portion 334 formed to extend in a foldable manner from the other end thereof. In addition, the engagement portion 334 may be folded to be in contact with the other side of the side cover 320. This is to improve a force of protecting the outer appearance of the display device by coupling the engagement portion 334 to the other side of the side cover 320 in the state in which the folio cover 330 is folded in the second state. In this regard, the engagement portion 334 and the other side of the side cover 320 may be attached to each other via a magnetic force using a magnet. In addition, they may also be coupled together via a separate coupling structure, for example, an engagement structure using a hook.

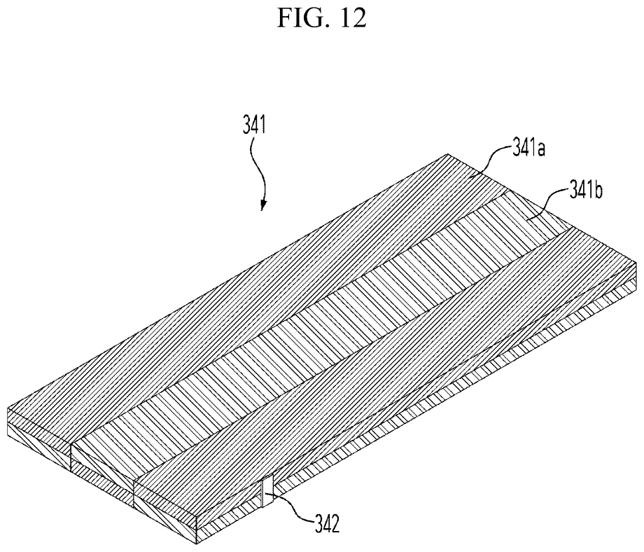

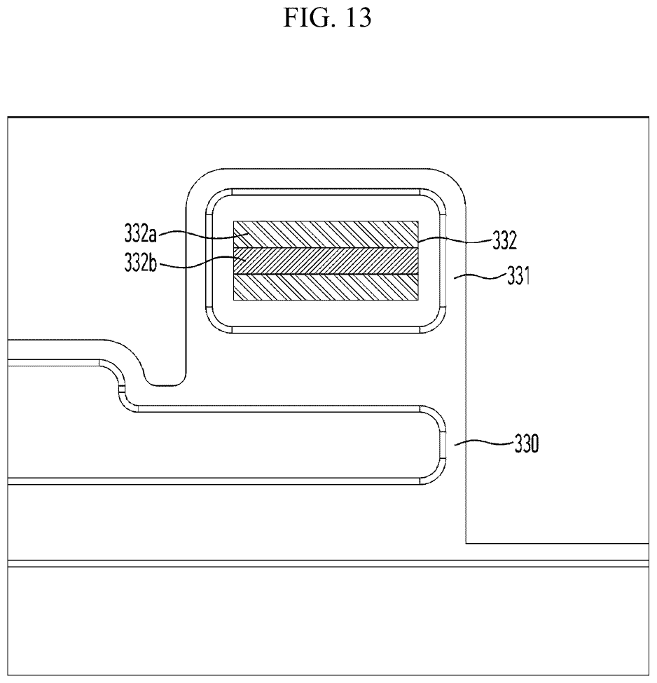

FIG. 12 is a view illustrating another embodiment of the first magnet 341 in the display device casing 300 according to the present disclosure. Further, FIG. 13 is a view illustrating another embodiment of the second magnet 332 positioned at the portion-to-be-inserted 331 of the folio cover 330 in the display device casing 300 according to the present disclosure.

As described above with reference to FIGS. 2 to 11, the display device casing 300 according to an embodiment of the present disclosure may secure the adhesive force of the folio cover 330 via the insertion structure in which the portion-to-be-inserted 331 of the folio cover 330 is inserted into the fastening groove 321 defined in the side cover 320 and the magnetic force between the first magnet 341 and the second magnet 332. In this regard, the size of the area for generating the magnetic force may be increased via the arrangement structure of the first magnet 341 and the second magnet 332, thereby securing the adhesive force of the folio cover 330.

In addition, in the display device casing 300 according to an embodiment of the present disclosure, an N-pole magnet and an S-pole magnet may be alternately arranged as shown in FIGS. 12 and 13 to secure the magnetic force between the first magnet 341 and the second magnet 332.

That is, the first magnet 341 may be formed by coupling a plurality of magnets to each other with an N-pole 341a and an S-pole 341b alternately arranged on one surface thereof. In addition, the second magnet 332 may be formed by coupling a plurality of magnets to each other with an S-pole 332a and an N-pole 332b alternately arranged on one surface thereof to generate the magnetic force with the N-pole 341a and the S-pole 341b of the first magnet 341.

Accordingly, in the display device casing 300 according to an embodiment of the present disclosure, as the N-poles 341a and 332b and the S-poles 341b and 332a are alternately arranged on the respective one surfaces generating the magnetic force of the first magnet 341 and the second magnet 332, the magnetic force generated between the first magnet 341 and the second magnet 332 is increased, thereby further improving the adhesive force of the folio cover 330.

Furthermore, when the portion-to-be-inserted 331 of the folio cover 330 is inserted into the fastening groove 321 defined in the side cover 320, the display device casing 300 according to an embodiment of the present disclosure may reduce a repulsive force between the first magnet 341 and the second magnet 332 where the N-pole magnet and the S-pole magnet are alternately disposed.

That is, the repulsive force that may occur during close proximity may be reduced when the N-pole and the S-pole are alternately disposed on the surface generating the magnetic force, compared to a case in which one N-pole or one S-pole is formed on the surface generating the magnetic force. Accordingly, the portion-to-be-inserted 331 of the folio cover 330 may be inserted into the fastening groove 321 without distortion, thereby further increasing user convenience.

In addition, referring to FIGS. 7, 12, and 13 together, in the display device casing 300 according to an embodiment of the present disclosure, the first magnet 341 may include a marking plate 342 coupled to one side surface thereof. This is to increase convenience of positioning the first magnet 341, in which the N-pole magnet and the S-pole magnet are alternately arranged and coupled to each other, at the fixing bracket 340 when manufacturing the display device casing 300 of the present disclosure.

This is because when a direction in which the first magnet 341 is located is wrong, the repulsive force may be generated instead of generating the magnetic force with the second magnet 332.

Accordingly, when the display device 300 of the present disclosure is manufactured, the first magnet 341 may be correctly positioned at the fixing bracket 340 via the marking plate 342 coupled to one side surface of the first magnet 341.

In addition, in the display device casing 300 according to an embodiment of the present disclosure, the marking plate 342 may also be coupled to one side surface of the second magnet 332. Accordingly, the second magnet 332 may be positioned in a correct direction at the portion-to-be-inserted 331 of the folio cover 330 during the manufacturing process, thereby generating the magnetic force with the first magnet 341 positioned at the fixing bracket 340.

In summary, the display device casing according to the present disclosure may increase the adhesive force of the folio cover via the structure in which the portion-to-be-inserted formed at one end of the folio cover is inserted into the fastening groove defined in the side cover. In addition, the adhesive force of the folio cover may be increased by minimizing the gap between the magnets for fastening the folio cover and increasing the area size for generating the magnetic force. In addition, the foreign substances that may be introduced via the fastening groove after the folio cover is fastened may be blocked via the fixing rib formed to protrude from the front surface of the rear cover.

The above detailed description is to be construed in all aspects as illustrative and not restrictive. The scope of the present disclosure should be determined by reasonable interpretation of the appended claims and all changes coming within the equivalency range of the present disclosure are intended to be embraced in the scope of the present disclosure.

What is claimed is:

1. A display device casing comprising:
a rear cover covering a rear surface of a display module;
a side cover surrounding peripheries of side surfaces of the display module and having a fastening groove defined at one side thereof;
a folio cover having a portion-to-be-inserted formed at one end thereof to be inserted into the fastening groove; and
a fixing bracket coupled to one side of the side cover and including a first magnet having one surface in contact with one surface of the inserted portion-to-be-inserted,
wherein the portion-to-be-inserted includes a second magnet generating a magnetic force with the first magnet.

2. The display device casing of claim 1, wherein the first magnet has the one surface formed by coupling a plurality of magnets to each other with an N-pole and an S-pole alternately arranged.

3. The display device casing of claim 2, wherein the second magnet has one surface formed by coupling a plurality of magnets to each other with an S-pole and an N-pole alternately arranged to generate the magnetic force with the N-pole and the S-pole of the first magnet.

4. The display device casing of claim 3, wherein the first magnet includes a marking plate coupled to one side surface thereof.

5. The display device casing of claim 1, wherein the first magnet has the one surface disposed to be perpendicular to an inner surface of the side cover.

6. The display device casing of claim 1, wherein the rear cover includes a fixing rib protruding from a front surface thereof and in contact with an opposite surface of the inserted portion-to-be-inserted.

7. The display device casing of claim 6, wherein the fixing rib is formed to be inclined to protrude from one side toward an inner side of the rear cover.

8. The display device casing of claim 7, wherein the fixing rib includes a plurality of fixing ribs spaced apart from each other and formed in parallel with each other.

9. The display device casing of claim 1, wherein the folio cover includes a bent portion so as to be foldable,
wherein the folio cover has an opposite end in contact with one side of a rear surface of the rear cover in a state of being folded in a first state.

10. The display device casing of claim 9, wherein the rear cover includes an engagement groove defined in the rear surface thereof, wherein the opposite end of the folio cover is inserted into the engagement groove.

11. The display device casing of claim 10, wherein the folio cover includes an engagement portion formed to extend in a foldable manner from the opposite end thereof,
wherein the engagement portion is folded and inserted into the engagement groove.

12. The display device casing of claim 11, wherein the engagement groove includes a plurality of engagement grooves spaced apart from each other and formed in parallel with each other.

13. The display device casing of claim 9, wherein the folio cover covers a front surface of the display module in a state of being folded in a second state.

14. The display device casing of claim 13, wherein the folio cover includes an engagement portion formed to extend in a foldable manner from the opposite end thereof,
wherein the engagement portion is folded and comes into contact with an opposite side of the side cover.
